(19) United States
(12) Patent Application Publication
(10) Pub. No.: US 2026/0247975 A1
(43) Pub. Date: Aug. 20, 2026

(54) DIE TO WAFER BONDING STRUCTURE AND SEMICONDUCTOR PACKAGE MANUFACTURED USING THE SAME

(71) Applicant: SAMSUNG ELECTRONICS CO., LTD., Suwon-si (KR)

(72) Inventors: Bongsik CHOI, Suwon-si (KR); Nayeon KIM, Suwon-si (KR); Jae-Wha PARK, Suwon-si (KR); Kyu-Ha LEE, Suwon-si (KR); Daeyeon CHO, Suwon-si (KR)

(73) Assignee: SAMSUNG ELECTRONICS CO., LTD., Suwon-si (KR)

(21) Appl. No.: 19/374,470

(22) Filed: Oct. 30, 2025

(30) Foreign Application Priority Data
Feb. 18, 2025 (KR) 10-2025-0021101

(51) Int. Cl. H10W 42/00; H10W 72/00; H10W 90/00

(52) U.S. Cl. CPC H10W 42/121; H10W 72/0198; H10W 90/792

(57) ABSTRACT

As one embodiment, the present disclosure provides a die to wafer bonding structure comprising: a wafer structure; a semiconductor die disposed on the wafer structure an having a first surface of the semiconductor die faces the wafer structure and a second surface opposite to the first surface, the semiconductor die including a first conductive pad disposed on the second surface; a plurality of dummy structures spaced apart from the semiconductor die on the wafer structure; and an insulation material surrounding each of the semiconductor die and the plurality of dummy structures.

### CROSS-REFERENCE TO RELATED APPLICATION

This application claims priority to and the benefit of Korean Patent Application No. 10-2025-0021101 filed with the Korean Intellectual Property Office on February 18, 2025, the entire contents of which are incorporated herein by reference.

### BACKGROUND OF THE INVENTION

### Field of the Invention

The present invention relates to a die to wafer bonding structure and a semiconductor package manufactured using the same.

### Description of the Related Art

In the semiconductor industry, 3D-IC technology, which stacks a plurality of semiconductor dies in a vertical direction, is known as a technology for high integration, high density, and high performance of products. Methods for stacking semiconductor dies can be broadly divided into die to wafer bonding, which bonds individual semiconductor dies to a wafer, die to die bonding, which bonds individual semiconductor dies to each other, and wafer to wafer bonding, which bonds wafers to each other. In a die to wafer bonding structure, a gap between the semiconductor dies can be filled with an insulation material.

### SUMMARY OF THE INVENTION

In one aspect, the present disclosure is to provide a die to wafer bonding structure capable of preventing dishing of an insulation material and a semiconductor package manufactured using the same.

As one embodiment, the present disclosure provides a die to wafer bonding structure comprising: a wafer structure; a semiconductor die disposed on the wafer structure and having a first surface facing the wafer structure and a second surface opposite to the first surface, the semiconductor die including a first conductive pad disposed on the second surface; a plurality of dummy structures spaced apart from the semiconductor die on the wafer structure; and an insulation material surrounding each of the semiconductor die and the plurality of dummy structures.

As another embodiment, the present disclosure provides a die to wafer bonding structure comprising: a wafer structure; a first semiconductor die disposed on the wafer structure; a second semiconductor die spaced apart from the first semiconductor die in a first direction on the wafer structure; a third semiconductor die spaced apart from the first semiconductor die in a second direction intersecting the first direction on the wafer structure; a fourth semiconductor die spaced apart from the second semiconductor die in the second direction on the wafer structure; a plurality of first dummy structures including a plurality of first-first dummy structures disposed between the first semiconductor die and the second semiconductor, a plurality of first-second dummy structures disposed between the first semiconductor die and the third semiconductor, a plurality of first-third dummy structures disposed between the second semiconductor die and the fourth semiconductor, and a plurality of first-fourth dummy structures disposed between the third semiconductor die and the fourth semiconductor; a plurality of second dummy structures surrounded by the plurality of first-first dummy structures, the plurality of first-second dummy structures, the plurality of first-third dummy structures and the plurality of first-fourth dummy structures; and an insulation material surrounding each of the first semiconductor die, the second semiconductor die, the third semiconductor die, the fourth semiconductor die, the plurality of first dummy structures, and the plurality of second dummy structures.

As another embodiment, the present disclosure provides a semiconductor package comprising: a first sub-package including a first semiconductor die, a plurality of first dummy structures spaced apart from the first semiconductor die, and a first insulation material surrounding each of the first semiconductor die and the plurality of first dummy structures; and a second sub-package disposed on the first sub-package, comprising a second semiconductor die disposed on the first semiconductor die and electrically connected to the first semiconductor die, a plurality of second dummy structures spaced apart from the second semiconductor die, and a second insulation material surrounding each of the second semiconductor die and the plurality of second dummy structures.

As another embodiment, the present disclosure provides a die to wafer bonding structure manufacturing method comprising: arranging semiconductor dies before processed on a wafer structure; removing a portion of each of the semiconductor dies before processed to provide semiconductor dies after processed and dummy structures that are separated from each other; forming an insulation material covering the semiconductor dies after processed and the dummy structures; and removing a portion of the insulation material to expose upper surfaces of the semiconductor dies.

According to one aspect of the present disclosure, a die to wafer bonding structure capable of preventing dishing of an insulation material and a semiconductor package manufactured using the same can be provided.

### BRIEF DESCRIPTION OF THE DRAWINGS

FIG. 1 is a cross-sectional view of a die to wafer bonding structure according to an embodiment.

FIG. 2 is a top view of the die to wafer structure illustrated in FIG. 1.

FIG. 3 is a cross-sectional view of a die to wafer bonding structure according to another embodiment.

FIG. 4 is a cross-sectional view of a die to wafer bonding structure according to another embodiment.

FIGS. 5, 6, 7, 8, 9, 10, 11, 12, 13, and 14 are drawings showing a manufacturing process of the die to wafer bonding structure illustrated in FIG. 1.

FIG. 15 is a cross-sectional view of a semiconductor package according to an embodiment.

FIG. 16 shows a layout between the semiconductor die and dummy structures of each sub-package included in the semiconductor package illustrated in FIG. 15.

FIGS. 17, 18, and 19 are drawings showing a manufacturing process of the semiconductor package illustrated in FIG. 15.

FIG. 20 is a cross-sectional view of a semiconductor package according to another embodiment.

FIG. 21 is a cross-sectional view of a semiconductor package according to another embodiment.

FIG. 22 is a cross-sectional view of a semiconductor package according to another embodiment.

FIG. 23 is a cross-sectional view of a semiconductor package according to another embodiment.

FIG. 24 and FIG. 25 are drawings showing a partial manufacturing process of a die to wafer bonding structure according to a comparative example.

### DETAILED DESCRIPTION OF THE EMBODIMENTS

Hereinafter, with reference to the accompanying drawing, various embodiments of the present disclosure are described in detail so that a person of ordinary skill in the art to which the present disclosure belongs may easily practice the present disclosure. The present disclosure may be implemented in many different forms and is not limited to the embodiments described herein.

In order to clearly explain the present disclosure, parts that are not related to the explanation have been omitted, and the same reference symbols are used for identical or similar components throughout the specification.

In addition, the size and thickness of each component shown in the drawing are arbitrarily shown for better understanding and ease of description, so the present disclosure is not necessarily limited to what is shown. In the drawings, the thickness of layers, films, panels, regions, etc., are exaggerated for clarity. And in the drawing, for better understanding and ease of description, the thickness of some layers and regions is exaggerated.

Throughout the specification, when it is described that an element is “connected” to another element, this includes not only cases where it is “directly connected” but also cases where it is “indirectly connected” through another member. From a similar perspective, this includes not only being “physically connected” but also being “electrically connected”.

Additionally, it will be understood that when an element such as a layer, film, region, or substrate is referred to as being “on” another element, it may be directly on another element or intervening elements may also be present. In contrast, when an element is referred to as being “directly on” another element, there are no intervening elements present. Also, being “above” or “on” the referenced part means being positioned above or below the referenced part, and does not necessarily mean being positioned “above” or “on” the opposite direction of gravity.

Additionally, unless explicitly described to the contrary, the word “comprise”, and variations such as “comprises” or “comprising”, will be understood to imply the inclusion of stated elements but not the exclusion of any other elements.

Also, throughout the specification, the phrase “in a plan view” means when an object portion is viewed from above, and the phrase “in a cross-sectional view” means when a cross-section taken by vertically cutting an object portion is viewed from the side.

Additionally, throughout the specification, the sequential numbers, such as first, second, etc., are used to distinguish a component from other identical or similar components, and are not necessarily intended to refer to a specific component. Thus, a component referred to as a first component in a particular part of the specification may be referred to as a second component in another part of the specification.

Additionally, throughout the specification, a singular reference to any component includes a plurality of references to that component, unless otherwise stated.

Additionally, throughout the specification, references to one surface and the other surface are intended to distinguish between different surfaces and are not necessarily intended to be limited to a particular surface. Accordingly, a surface referred to as one surface in a particular part of this specification may be referred to as the other surface in another part of this specification.

Additionally, throughout the specification, references to directions such as top, upper side, upper side, lower side, lower side, etc. are described to aid explanation and understanding based on the drawings.

Hereinafter, a die to wafer bonding structure and a semiconductor package manufactured using the same according to embodiments of the present disclosure are described with reference to the drawings.

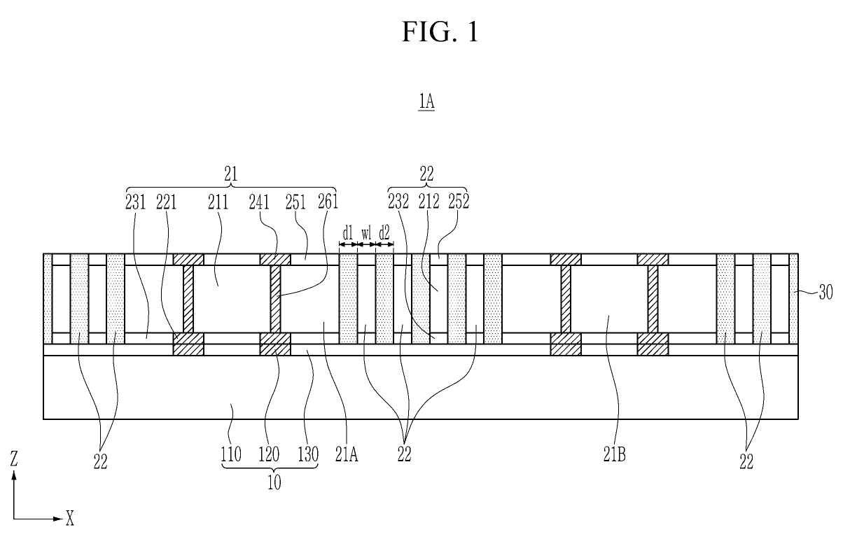

FIG. 1 is a cross-sectional view of a die to wafer bonding structure according to an embodiment.

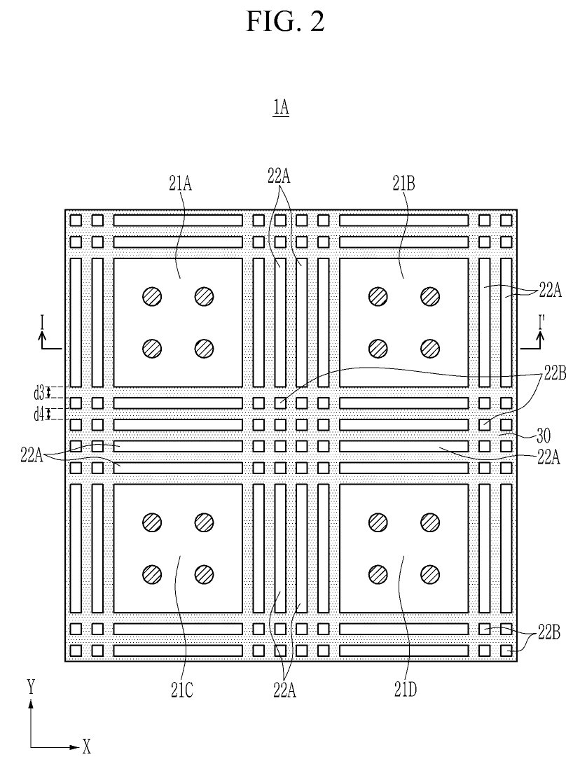

FIG. 2 is a top view of the die to wafer structure illustrated in FIG. 1.

FIG. 1 is a cross-sectional view of FIG. 2 taken along the I-I' direction.

A die to wafer bonding structure 1A according to an embodiment may include a wafer structure 10, a plurality of semiconductor dies 21 spaced apart from each other on the wafer structure 10, a plurality of dummy structures 22 spaced apart from the plurality of semiconductor dies 21 on the wafer structure 10, and an insulation material 30 surrounding each of the plurality of semiconductor dies 21 and the plurality of dummy structures 22.

The wafer structure 10 includes a wafer 110 and may further include a first conductive pad 120 disposed on the wafer 110 and a first insulation layer 130 disposed on the wafer 110 and embedding the first conductive pad 120.

The wafer 110 may be a semiconductor wafer containing semiconductor material. For example, the wafer 110 may include a semiconductor such as silicon (Si), germanium (Ge), or a compound semiconductor such as gallium arsenide (GaAs), silicon carbide (SiC).

In an embodiment, the wafer structure 10 may be electrically connected to the semiconductor die 21 and serve as a substrate. In the wafer structure 10 that serves as a substrate, wiring layers electrically connected to the semiconductor die 21 through the first conductive pad 120 and an insulation layer embedding the wiring layers may be formed on an upper surface of the wafer 110.

The first conductive pad 120 may be electrically connected to the semiconductor die 21. The first conductive pad 120 may be embedded in the first insulation layer 130, but an upper surface of the first conductive pad 120 may be exposed from the first insulation layer 130 for electrical connection. The first conductive pad 120 may include a conductive material, for example, a metal such as aluminum (Al), copper (Cu), tungsten (W), gold (Au), platinum (Pt), silver (Ag), tin (Sn), chromium (Cr), palladium (Pd), or an alloy of two or more of these. The first conductive pad 120 may have various shapes, such as a circular shape, a polygon such as a quadrangle or a hexagon in a plan view.

The first insulation layer 130 may protect a surface of the wafer structure 10 and perform the role of bonding the wafer structure 10 to another component. The first insulation layer 130 may cover a side surface of the first conductive pad 120 and may not cover at least a portion of an upper surface of the first conductive pad 120. The first insulation layer 130 may include at least one of an insulating material, for example, silicon oxide, silicon nitride, silicon carbide nitride (SiCN), or benzocyclobutene (BCB).

Depending on the embodiment, the wafer structure 10 may not include the first conductive pad 120 and/or the first insulation layer 130.

The semiconductor dies 21 may be arranged along an X direction and a direction intersecting therewith, for example, the X direction and a Y direction perpendicular thereto. In an embodiment, the semiconductor dies 21 may include a first semiconductor die 21A, a second semiconductor die 21B spaced apart from the first semiconductor die 21A in the X direction, a third semiconductor die 21C spaced apart from the first semiconductor die 21A in the Y direction, and a fourth semiconductor die 21D spaced apart from the second semiconductor die 21B in the Y direction and spaced apart from the third semiconductor die 21C in the X direction.

However, the drawing may only show a portion of the die to wafer bonding structure 1A, and the number of the semiconductor dies 21 arranged on the wafer structure 10 may be greater than shown in the drawing.

In an embodiment, each semiconductor die 21 may include a semiconductor substrate 211, a second conductive pad 221 disposed on a lower surface of the semiconductor substrate 211, a second insulation layer 231 disposed on the lower surface of the semiconductor substrate 211 and embedding the second conductive pad 221, a third conductive pad 241 disposed on a upper surface of the semiconductor substrate 211, a third insulation layer 251 disposed on the upper surface of the semiconductor substrate 211 and embedding the third conductive pad 241, and a through via 261 penetrating the semiconductor substrate 211 and electrically connecting the second conductive pad 221 and the third conductive pad 241.

In an embodiment, each semiconductor die 21 may be hybrid bonded with the wafer structure 10. The second conductive pad 221 of each semiconductor die 21 may be bonded by contacting with the first conductive pad 120 of the wafer structure 10, and the second insulation layer 231 may be bonded by contacting with the first insulation layer 130 of the wafer structure 10.

The semiconductor substrate 211 may include a semiconductor such as silicon (Si), germanium (Ge), or a compound semiconductor such as gallium arsenide (GaAs) or silicon carbide (SiC).

At least one of the upper and lower surfaces of the semiconductor substrate 211 may have wiring layers electrically connected to the second conductive pad 221 and the third conductive pad 241, and an insulation layer embedding the wiring layers.

The second conductive pad 221 may be electrically connected to the wafer structure 10. The second conductive pad 221 may be embedded in the second insulation layer 231, but a lower surface of the second conductive pad 221 may be exposed from the second insulation layer 231 for electrical connection.

The third conductive pad 241 may electrically connect the semiconductor die 21 to another component. The third conductive pad 241 may be embedded in the third insulation layer 251, but a upper surface of the third conductive pad 241 may be exposed from the third insulation layer 251 for electrical connection.

Each of the second conductive pad 221 and the third conductive pad 241 may include a conductive material, for example, a metal such as aluminum (Al), copper (Cu), tungsten (W), gold (Au), platinum (Pt), silver (Ag), tin (Sn), chromium (Cr), palladium (Pd), or an alloy of two or more of these. Each of the second conductive pad 221 and the third conductive pad 241 may have various shapes, such as a circular shape, a polygon such as a quadrangle or a hexagon in a plan view.

The second insulation layer 231 and the third insulation layer 251 may each protect a surface of the semiconductor die 21 and perform the role of bonding the semiconductor die 21 to another component. The second insulation layer 231 may cover a side surface of the second conductive pad 221 and may not cover at least a portion of a lower surface of the second conductive pad 221. The third insulation layer 251 may cover a side surface of the third conductive pad 241 and may not cover at least a portion of a upper surface of the third conductive pad 241. Each of the second insulation layer 231 and the third insulation layer 251 may include at least one of an insulating material, for example, silicon oxide, silicon nitride, silicon carbide nitride (SiCN), or benzocyclobutene (BCB).

The dummy structures 22 may be disposed between semiconductor dies 21. The dummy structures 22 may function as a stopping layer in the process of removing a region covering the upper surface of the semiconductor dies 21 of the insulation material 30 to expose the semiconductor dies 21, and may minimize dishing of the insulation material 30 in the region between the semiconductor dies 21.

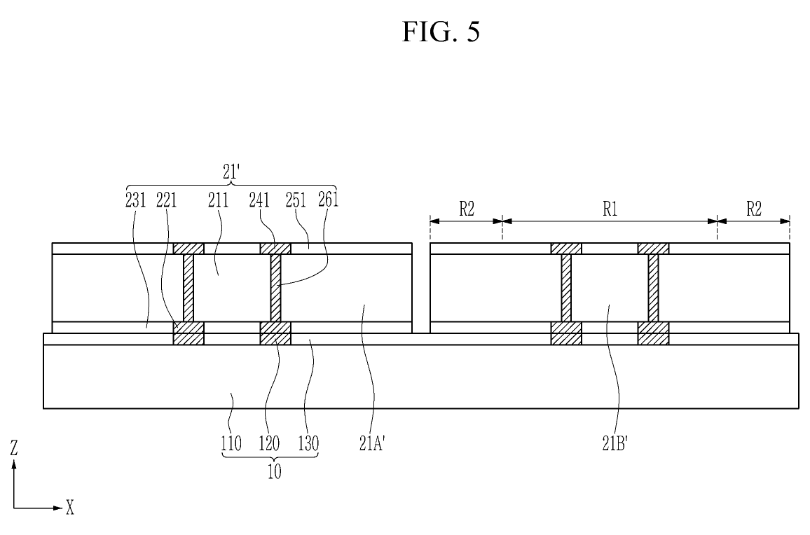

Each of the dummy structures 22 may be a dummy die separated from the semiconductor die 21 by removing a portion of the semiconductor die 21' which is before processed (see FIG. 5 to FIG. 14).

The dummy structures 22 may include first dummy structures 22A and second dummy structures 22B.

Based on each semiconductor die 21, the first dummy structures 22A may be disposed side by side with an adjacent semiconductor die 21. One side of the first dummy structure 22A arranged side by side with the adjacent semiconductor die 21 may be adjacent to (facing) one side of the adjacent semiconductor die 21.

Based on a plurality of semiconductor dies 21, the first dummy structures 22A may be disposed between the semiconductor dies 21 arranged side by side. Each side of the semiconductor dies 21 arranged side by side may face each other. For example, the first dummy structures 22A may include first-first dummy structures 22A disposed between the first semiconductor die 21A and the second semiconductor die 21B, first-second dummy structures 22A disposed between the first semiconductor die 21A and the third semiconductor die 21C, first-third dummy structures 22A disposed between the second semiconductor die 21B and the fourth semiconductor die 21D, and first-fourth dummy structures 22A disposed between the third semiconductor die 21C and the fourth semiconductor die 21D.

The first dummy structures 22A may be arranged in a direction from one semiconductor die 21 to the other semiconductor die 21 arranged on either side of the first dummy structures 22A. For example, the first-first dummy structures 22A disposed between the first semiconductor die 21A and the second semiconductor die 21B and the first-fourth dummy structures 22A disposed between the third semiconductor die 21C and the fourth semiconductor die 21D may be arranged along the X direction. Additionally, the first-second dummy structures 22A disposed between the first semiconductor die 21A and the third semiconductor die 21C and the first-third dummy structures 22A arranged between the second semiconductor die 21B and the fourth semiconductor die 21D may be arranged along the Y direction.

The first dummy structures 22A may extend in a direction perpendicular to the direction from one semiconductor die 21 to the other semiconductor die 21 arranged on either side thereof. For example, the first-first dummy structures 22A disposed between the first semiconductor die 21A and the second semiconductor die 21B and the first-fourth dummy structures 22A disposed between the third semiconductor die 21C and the fourth semiconductor die 21D may extend in the Y direction. Additionally, the first-second dummy structures 22A disposed between the first semiconductor die 21A and the third semiconductor die 21C and the first-third dummy structures 22A disposed between the second semiconductor die 21B and the fourth semiconductor die 21D may extend in the X direction.

Based on each semiconductor die 21, the second dummy structures 22B may be disposed adjacent to a corner of an adjacent semiconductor die 21. A corner of the second dummy structure 22B may face the corner of the adjacent semiconductor die 21.

Based on a plurality of semiconductor dies 21, the second dummy structures 22B may be disposed between the semiconductor dies 21 arranged in a diagonal direction with respect to each other. A diagonal direction may be a direction that intersects the X direction and the Y direction For example, a direction that forms an angle of approximately 45° with each of the X direction and the Y direction. Each corner of the semiconductor dies 21 arranged in a diagonal direction may face each other. For example, the second dummy structures 22B disposed at the center of FIG. 2 may be described as being disposed between the first semiconductor die 21A and the fourth semiconductor 21D or between the second semiconductor die 21B and the third semiconductor 21C, which are disposed in a diagonal direction with respect to each other.

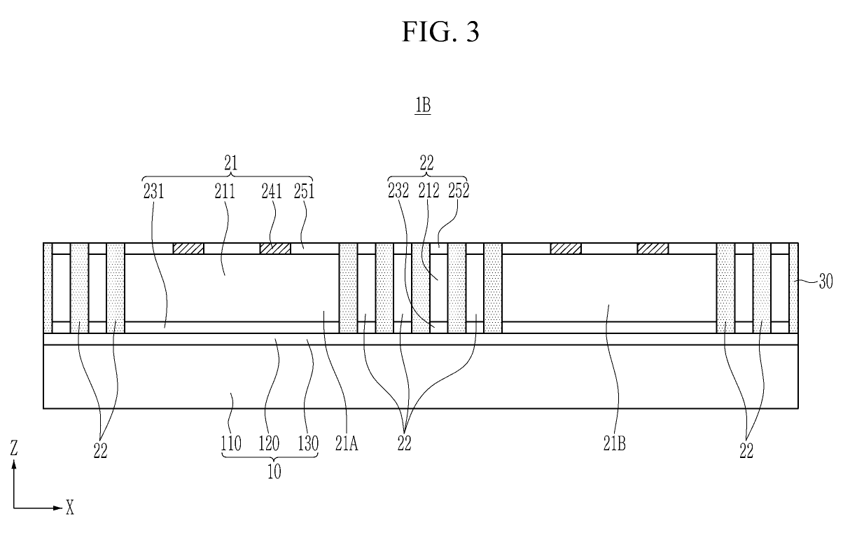

The second dummy structures 22B may also be understood as being surrounded by the first dummy structures 22A disposed between adjacent semiconductor dies 21 to the second dummy structures 22B. For example, the second dummy structures 22B disposed at the center of FIG. 3 may be described as being surrounded by the first-first dummy structures 22A disposed between the first semiconductor die 21A and the second semiconductor die 21B, the first-second dummy structures 22A disposed between the first semiconductor die 21A and the third semiconductor die 21C, the first-third dummy structures 22A disposed between the second semiconductor die 21B and the fourth semiconductor die 21D, and the first-fourth dummy structures 22A disposed between the third semiconductor die 21C and the fourth semiconductor die 21D.

The second dummy structures 22B may be arranged along the X direction and a direction intersecting therewith, for example, the X direction and the Y direction. The second dummy structures 22B may have a plurality of columns and a plurality of rows.

The second dummy structures 22B may have a shape of a square or rectangle in a plan view, but are not limited thereto.

The distance d1 between each semiconductor die 21 and a first dummy structure 22A most adjacent to the semiconductor die 21 among the first dummy structures 22A may be 50 µm or more and 100 µm or less. Additionally, the distance d2 between the first dummy structures 22A, the distance d3 between the first dummy structure 22A and the second dummy structure 22B and/or the distance d4 between the second dummy structures 22B may be 50 µm or more and 100 µm or less. The distance d1 between the semiconductor die 21 and the first dummy structure 22A, the distance d2 between the first dummy structures 22A, the distance d3 between the first dummy structure 22A and the second dummy structure 22B and/or the distance d4 between the second dummy structures 22B may be regions removed through dry etching (e.g., plasma etching) of the semiconductor die before processed 21’ (see FIG. 5 to FIG. 14). If the distances d1, d2, d3 and d4 are formed to be less than 50 µm, problems such as uneven etching, remaining PR residue, difficulty in charge of the insulation material 30, and occurrence of cracks due to stress may occur. In addition, if the distances d1, d2, d3 and d4 are formed to exceed 100 µm, it may be difficult to prevent dishing of the insulation material 30 in the region between the semiconductor dies 21, and the process time may be prolonged. As one exemplary measurement method of the aforementioned distances, a “distance” between two elements having surfaces facing each other may mean an average value of shortest distances between two targeted surfaces of the respective elements measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

The width w1 of each of the dummy structures 22 may be greater than or equal to 50 µm and less than or equal to 100 µm. The width of the first dummy structure 22A may refer to a width in a direction from one semiconductor die 21 to the other semiconductor die 21 arranged on either side of the first dummy structure 22A, and the width of the second dummy structure 22B may refer to a width in the X direction and a width in the Y direction. If the width w1 of each of the dummy structures 22 is less than 50 µm, it may be difficult for the dummy structure 22 to function as a processing stop layer when removing the insulation material 30, and the process may become complicated due to the formation of a number of dummy structures 22. Additionally, when applying dry etching, it may be difficult to form each of the dummy structures 22 with the width w1 of less than 50 µm due to process limitations. If the width w1 of each of the dummy structures 22 exceeds 100 µm, a space for placing a plurality of semiconductor dies 21 may be limited. As one exemplary measurement method of the aforementioned widths, a “width” of an element having two opposing surfaces may mean an average value of shortest distances between the two targeted surfaces measured in a direction perpendicular to the targeted surfaces at multiple locations (e.g., 3, 5, or 10) at equal intervals (or non-equal intervals, alternatively). Other methods appreciated by one of ordinary skill in the art, even if not described in the present disclosure, may also be used.

Each of the dummy structures 22 includes a semiconductor substrate 212 and may further include an insulation layer 232, 252 disposed on at least one surface of the semiconductor substrate 212. In an embodiment, each dummy structure 22 may include a semiconductor substrate 212, a fourth insulation layer 232 disposed on a lower surface of the semiconductor substrate 212, and a fifth insulation layer 252 disposed on an upper surface of the semiconductor substrate 212.

In an embodiment, the dummy structure 22 may be directly bonded to the wafer structure 10, similar to the semiconductor die 21. For example, the fourth insulation layer 232 of the dummy structure 22 may be bonded by contacting with the first insulation layer 130 of the wafer structure 10.

The semiconductor substrate 212 may include a semiconductor such as silicon (Si), germanium (Ge), or a compound semiconductor such as gallium arsenide (GaAs) or silicon carbide (SiC).

Each of the fourth insulation layer 232 and the fifth insulation layer 252 of the dummy structure 22 may include at least one of an insulating material, for example, silicon oxide, silicon nitride, silicon carbide nitride (SiCN), or benzocyclobutene (BCB).

As the semiconductor die 21' which is before processed is separated to form the semiconductor die 21 and the dummy structure 22, the thickness of the dummy structure 22 may be substantially the same as the thickness of the semiconductor die 21. Additionally, the thicknesses of the semiconductor substrate 212, the fourth insulation layer 232, and the fifth insulation layer 252 of the dummy structure 22 may be substantially the same as the thicknesses of the semiconductor substrate 211, the second insulation layer 231, and the third insulation layer 251 of the semiconductor die 21, respectively. As used herein, the expression “substantially the same” may refer to having the same value relative to other value(s) compared therewith, as will be appreciated by those of skill in the art, and allows for approximations, inaccuracies and limits of measurement under the relevant circumstances. In one or more aspects, the terms “substantially,” “about,” and “approximately” may provide an industry-accepted tolerance for their corresponding terms and/or relativity between items, such as a tolerance of ± 1%, ± 5% , or ± 10% of the actual value stated, and other suitable tolerances.

The insulation material 30 may surround each of the semiconductor dies 21 and the dummy structures 22. Additionally, the insulation material 30 may fill at least a portion of each of the space between the semiconductor die 21 and the dummy structure 22 and the space between the dummy structures 22 on the wafer structure 10. The insulation material 30 may include an insulating material, for example, at least one of silicon oxide, silicon nitride, and Tetra-ethyl-ortho-silicate (TEOS).

The insulation material 30 may be formed to cover the semiconductor dies 21 and the dummy structures 22 disposed on the wafer structure 10, and the region of the insulation material 30 covering upper surfaces of the semiconductor dies 21 and the dummy structures 22 may be removed. Accordingly, the upper surface of each of the semiconductor dies 21 and the dummy structures 22 may be exposed from the insulation material 30. Removal of the insulation material 30 may be performed by chemical mechanical polishing (CMP).

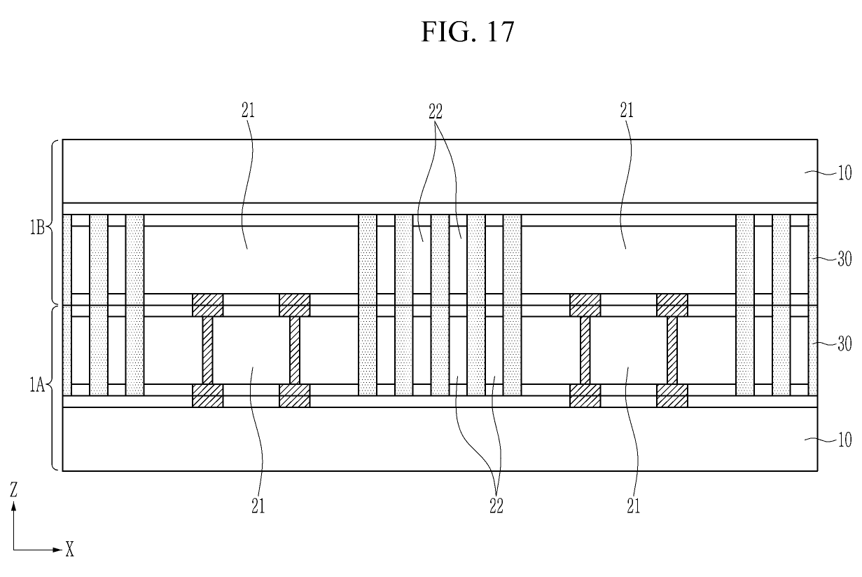

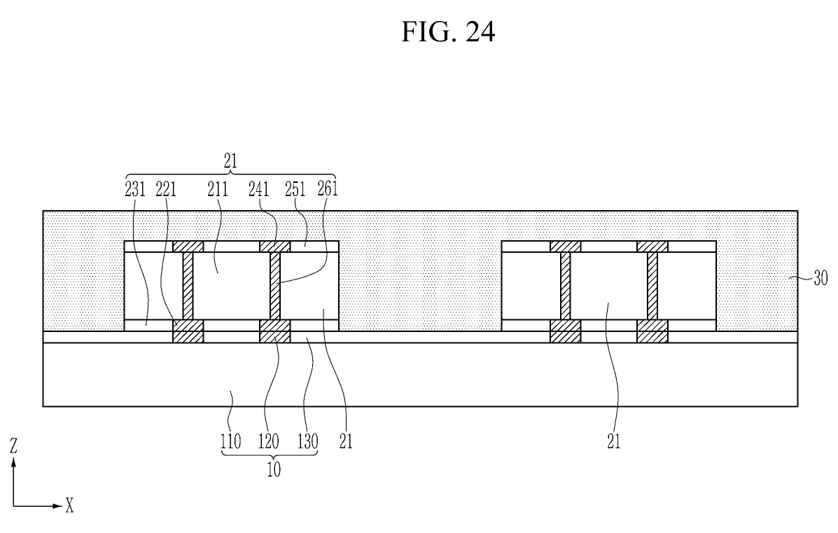

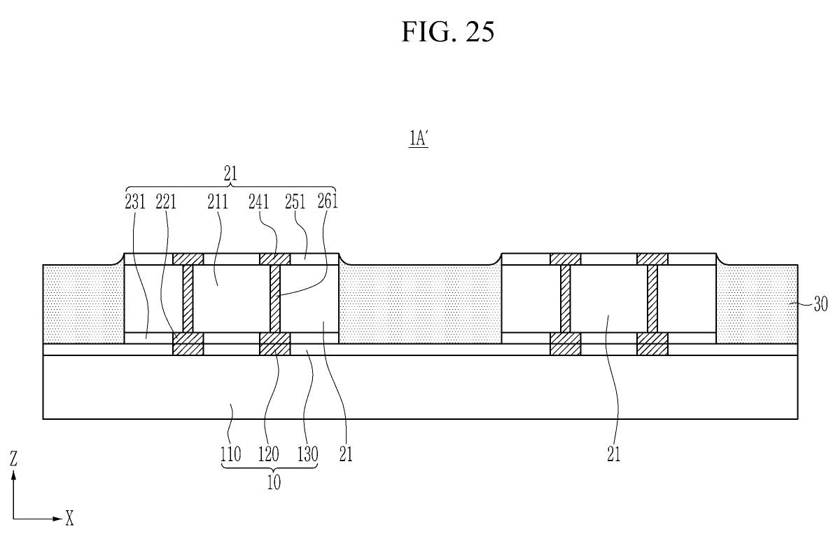

Meanwhile, dishing of the insulation material in the region between semiconductor dies may occur during the process of removing the upper surface of the insulation material by chemical mechanical polishing (see FIG. 24 and FIG. 25). Dishing of the insulation material may cause voids between the insulation materials during bonding between die to wafer bonding structures in subsequent processes (see FIG. 17), resulting in reduced product yield.

According to the present disclosure, dishing of the insulation material may be prevented by introducing dummy structures between semiconductor dies. Therefore, process difficulty and cost increase for dishing control of the insulation material are not required, and voids between insulation materials due to dishing and a decrease in product yield due to voids can be prevented.

If the dummy structure is formed separately from the semiconductor die, it may be difficult to manufacture a small-sized dummy structure, and bonding a dummy structure to the wafer structure may also be difficult. The dummy structure 22 according to the present disclosure may be formed by patterning the semiconductor die 21’, and a small-sized dummy structure 22 may be easily introduced onto the wafer structure 10.

FIG. 3 is a cross-sectional view of a die to wafer bonding structure according to another embodiment.

The wafer structure 10 of a die to wafer bonding structure 1B may not include a first conductive pad 120, and/or the semiconductor die 21 may not include a second conductive pad 221 and a through via 261.

The wafer structure 10 may be electrically insulated from the semiconductor dies 21 and may serve as a carrier substrate for the semiconductor dies 21 during bonding the die to wafer bonding structure 1B to another component.

The semiconductor die 21 and dummy structure 22 may be fusion bonded with the wafer structure 10. For example, the second insulation layer 231 of the semiconductor die 21 and the fourth insulation layer 232 of the dummy structure 22 may be bonded by contacting with the first insulation layer 130 of the wafer structure 10. Alternatively, the semiconductor substrate 211 of the semiconductor die 21 and the semiconductor substrate 212 of the dummy structure 22 may be bonded by contacting with the wafer 110 of the wafer structure 10 (the first insulation layer 130, the second insulation layer 231, and the fourth insulation layer 232 may be omitted).

Alternatively, each semiconductor die 21 may be bonded to the wafer structure 10 via another component, such as an adhesive.

For other configurations, the same explanations as specifically described elsewhere in the present disclosure may be applied.

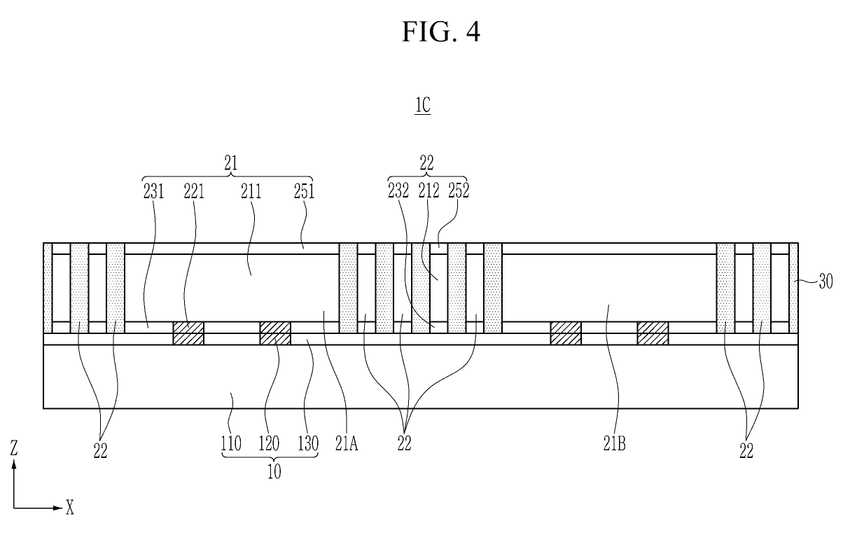

FIG. 4 is a cross-sectional view of a die to wafer bonding structure according to another embodiment.

Depending on the embodiment, the semiconductor die 21 of a die to wafer bonding structure 1C may not include the third conductive pad 241 and the through via 261. Depending on the embodiment, the semiconductor die 21 may not include a third insulation layer 251, and the dummy structure 22 may not include a fifth insulation layer 252. The die to wafer bonding structure 1C may be used for manufacturing products other than 3D-IC.

For other configurations, the same explanations as specifically described elsewhere in the present disclosure may be applied.

FIG. 5 to FIG. 14 are drawings showing a manufacturing process of the die to wafer bonding structure illustrated in FIG. 1.

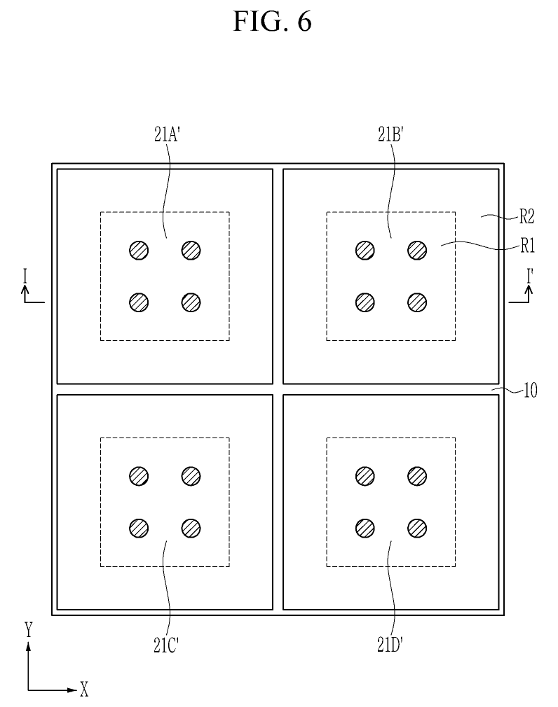

FIG. 5, 7, 9, 10, 12 and 13 are cross-sectional views of the die to wafer bonding structure at each step. FIGS. 6, 8, 11, and 14 are top views of the die to wafer bonding structure at each step.

A manufacturing method of a die to wafer bonding structure according to an embodiment may include arranging semiconductor dies before processed 21' on a wafer structure 10, removing a portion of each of the semiconductor dies before processed 21' to provide semiconductor dies after processed 21 and dummy structures 22 that are separated from each other, forming an insulation material 30 covering the semiconductor dies after processed 21 and the dummy structures 22, and removing a portion of the insulation material 30 to expose upper surfaces of the semiconductor dies 21.

First, referring to FIG. 5 and FIG. 6 (a top view of FIG. 5, which is a cross-sectional view of FIG. 6 taken along the I-I' direction), semiconductor dies before processed 21' may be disposed on the wafer structure 10. The semiconductor dies before processed 21' may have a die region R1 and a dummy region R2. The die region R1 comprises a semiconductor die 21 after processing and may include wiring layers and conductive pads 221, 241, and through vias 261 to function as a semiconductor die. On the other hand, the dummy region R2 may not include configurations to function as a semiconductor die.

Next, a portion of each of the semiconductor dies before processed 21’ may be removed to provide the semiconductor dies after processed 21 and dummy structures 22 that are separated from each other. The region removed from the semiconductor die before processed 21’ may be part of the dummy region R2. The remaining region of the dummy region R2 that is not removed may provide the dummy structure 22 after the process. Among the removed regions of dummy region R2, the region adjacent to the die region R1 may separate the dummy structure 22 and the semiconductor die 21 after processing.

In an embodiment, a portion of each of the semiconductor dies before processed 21’ may be removed by an etching process utilizing a photoresist layer PR.

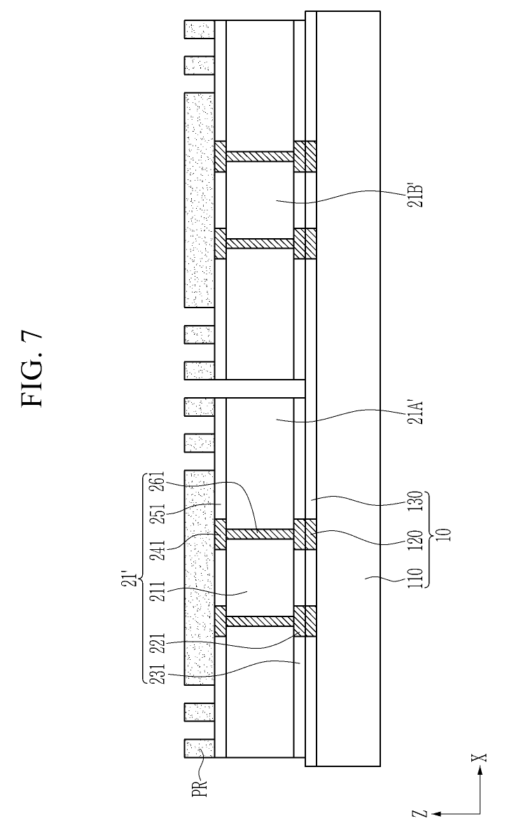

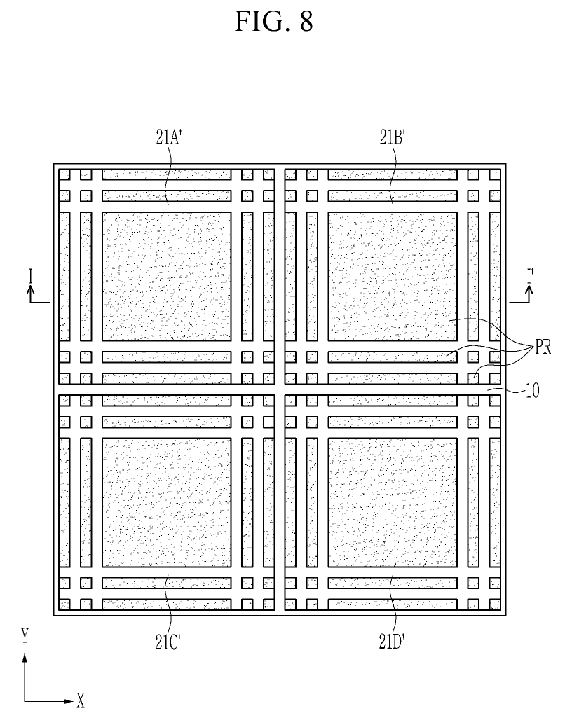

First, referring to FIG. 7 and FIG. 8 (a top view of FIG. 7, which is a cross-sectional view of FIG. 8 cut along the I-I' direction), a photoresist layer PR may be disposed on each semiconductor die before processed 21’, and the photoresist layer PR may be patterned. A photoresist layer PR may be patterned to cover the formation regions of the semiconductor die after processed 21 and dummy structures 22. Patterning of the photoresist layer PR may be performed by an exposing and developing process.

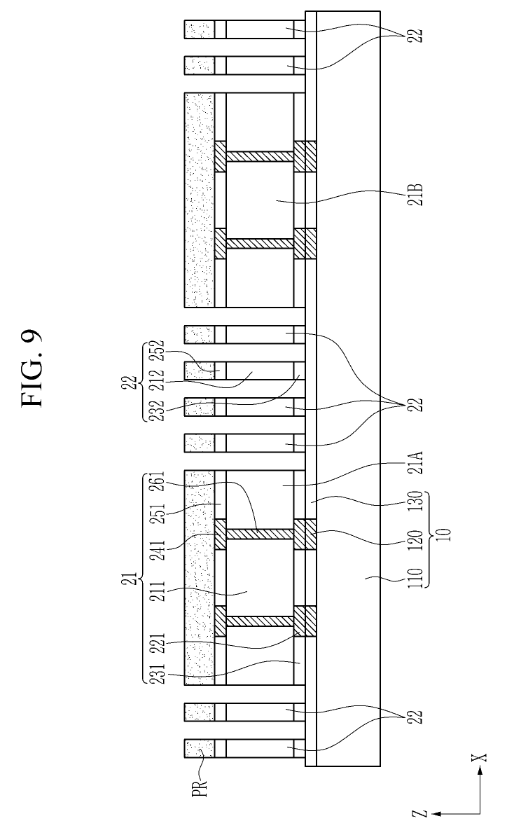

Next, referring to FIG. 9, the region not covered by the photoresist layer PR of the semiconductor die before processed 21 may be removed to form the semiconductor dies after processed 21 and dummy structures 22 that are separated from each other.

In the present disclosure, different symbols were used for the semiconductor substrate 212 and insulation layers 232, and 252 of the dummy structure 22 separated from the semiconductor die before processed 21’, compared to the semiconductor substrate 211 and insulation layers 231, and 251 of the semiconductor die before processed 21’ and the semiconductor die after processed 21.

In an embodiment, a portion of the semiconductor die before processed 21' may be removed by plasma etching, which is advantageous for forming a fine pattern. When plasma etching is applied, excellent anisotropic etching is possible and damage to the die region R1 may be prevented. However, a portion of the semiconductor die before processed 21' may be removed by another type of dry etching, or may be removed by other methods such as wet etching, laser processing, or blade processing. Depending on the processing depth, at least a portion of the insulation layer 231 of the semiconductor die before processed21’ may remain, in which case the insulation layers 231 and 232 of the semiconductor die after processed 21 and the dummy structure 22 may be connected.

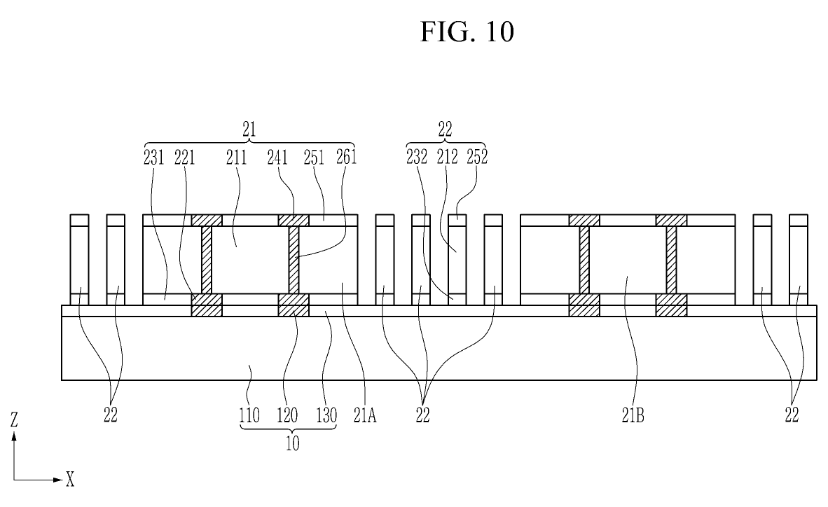

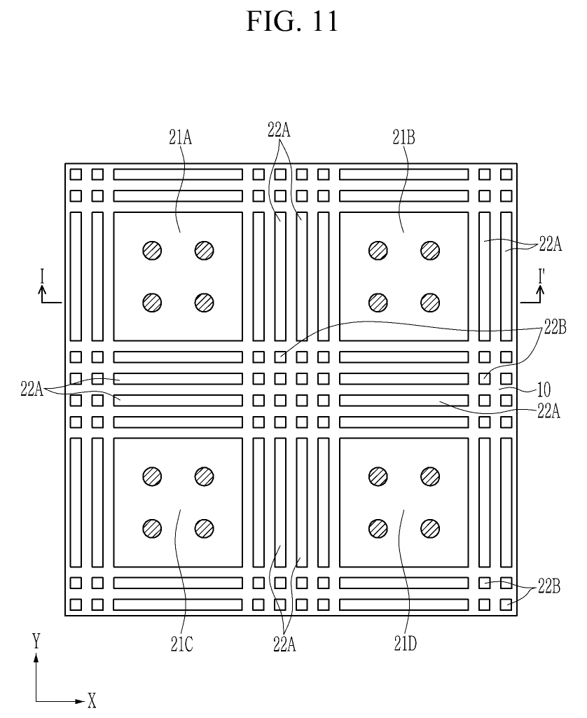

Next, referring to FIG. 10 and FIG. 11 (top view of FIG. 10, which is a cross-sectional view of FIG. 11 cut along the I-I' direction), the photoresist layer PR may be removed.

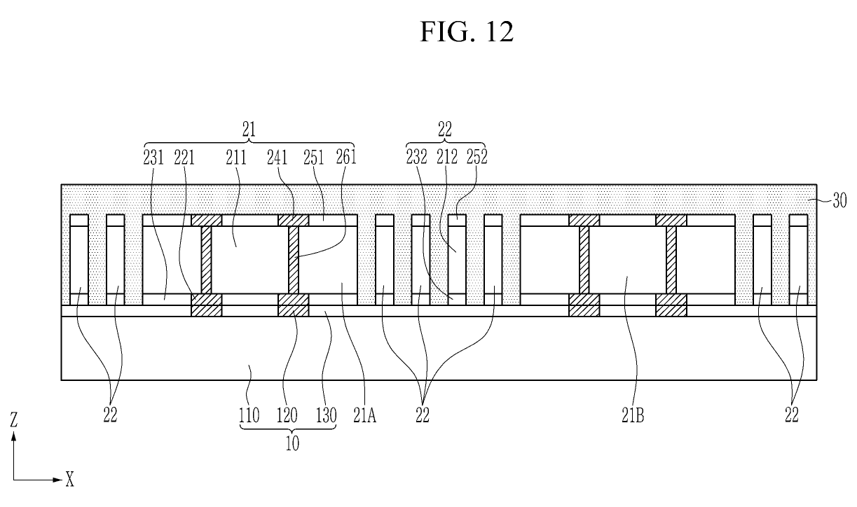

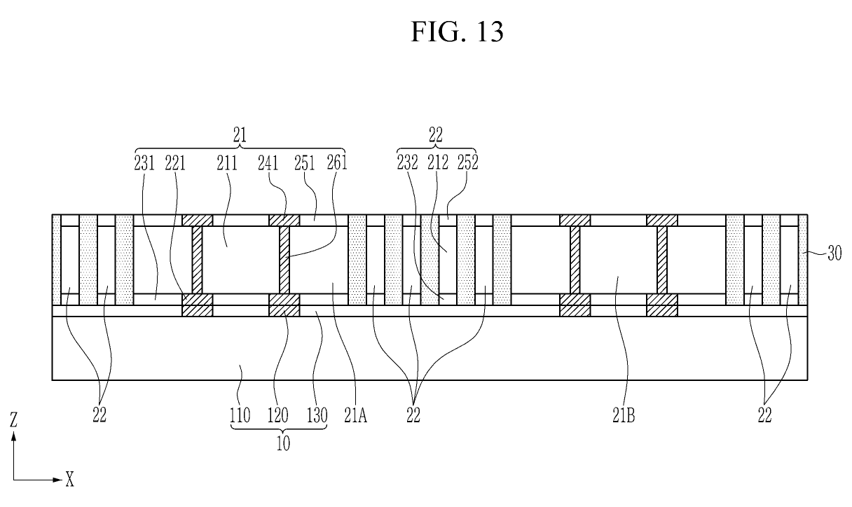

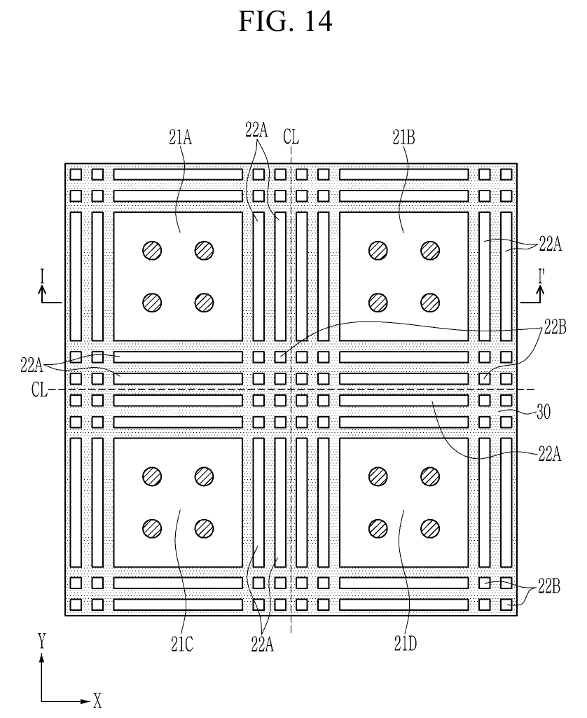

Next, referring to FIG. 12, 13 and FIG. 14 (a top view of FIG. 13, which is a cross-sectional view taken along the I-I' direction of FIG. 14), an insulation material 30 covering semiconductor dies after processed 21 and dummy structures 22 is formed, and a part of the insulation material 30 may be removed to expose the upper surfaces of the semiconductor dies 21. Removal of the insulation material 30 may be performed by chemical mechanical polishing (CMP). When the insulation material 30 is removed, the dummy structures 22 may function as a processing stop layer, and the upper surfaces of the dummy structures 22 may also be exposed from the insulation material 30.

The manufactured die to wafer bonding structure 1A may be cut along a cutting line CL and used in a subsequent process.

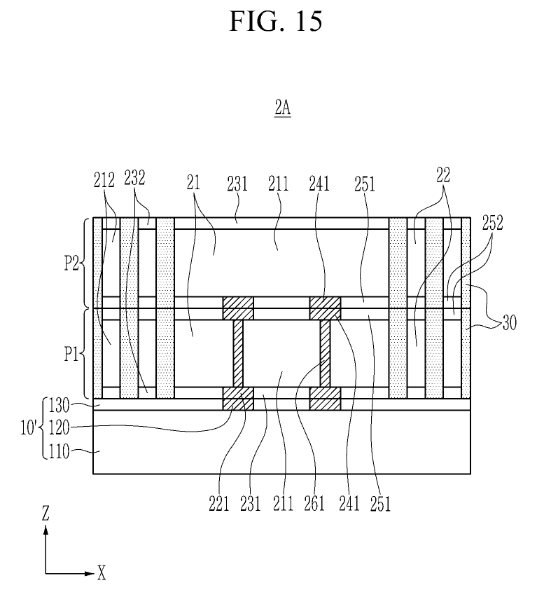

FIG. 15 is a cross-sectional view of a semiconductor package according to an embodiment.

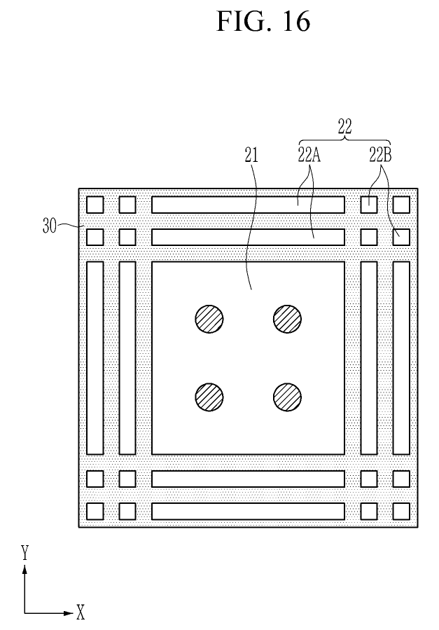

FIG. 16 shows the layout between the semiconductor die and dummy structures of each sub-package included in the semiconductor package illustrated in FIG. 15.

A semiconductor package 2A according to an embodiment may include a substrate 10' and a plurality of sub-packages P1, and P2 stacked on the substrate 10'. For example, the semiconductor package 2A may include a first sub-package P1 disposed on substrate 10' and a second sub-package P2 disposed on the first sub-package P1.

The substrate 10' may be formed by cutting the wafer structure 10. The substrate 10' may be electrically connected to the semiconductor die 21 of the first sub-package P1.

Each of the plurality of sub-packages P1 and P2 may be a structure excluding or removing the wafer structure 10 from one of the die to wafer bonding structures 1A, 1B, and 1C according to the present disclosure. The first sub-package P1 and the second sub-package P2 may be arranged so that their third conductive pads 241 face each other. Each of the plurality of sub-packages P1 and P2 may include a semiconductor die 21, a plurality of dummy structures 22 spaced apart from the semiconductor die 21, and an insulation material 30 surrounding each of the semiconductor die 21 and the plurality of dummy structures 22.

The second sub-package P2, which is disposed on the top side, may not include, but is not limited to, a second conductive pad 221 and a through via 261 for electrical connection to the upper component.

The semiconductor dies 21 of each of the plurality of sub-packages P1 and P2 may overlap in the Z direction, and be electrically connected to each other. The semiconductor dies 21 of each of the plurality of sub-packages P1 and P2 may be hybrid bonded and contacted.

The dummy structures 22 of each of the plurality of sub-packages P1 and P2 may be arranged to surround the semiconductor die 21. The dummy structures 22 may include the first dummy structures 22A disposed side by side with the semiconductor die 21 and second dummy structures 22B adjacent to an edge of the semiconductor die 21. The first dummy structures 22A may be disposed adjacent to a side of each sub-package P1 and P2, and the second dummy structures 22B may be disposed adjacent to a corner of each sub-package P1 and P2.

The dummy structures 22 of each of the plurality of sub-packages P1 and P2 may bonded by contacting. For example, the fifth insulation layer 252 of the dummy structure 22 of each of the first sub-package P1 and the second sub-package P2 may contact each other.

The insulation materials 30 of each of the plurality of sub-packages P1 and P2 may bonded by contacting. According to the present disclosure, by minimizing dishing of the insulation material 30 through dummy structures 22, voids between the insulation materials 30 of each sub-package P1 and P2 can be prevented, and excellent bonding strength can be secured.

For other configurations, the same explanations as specifically described elsewhere in the present disclosure may be applied.

FIG. 17 to FIG. 19 are drawings showing a manufacturing process of the semiconductor package illustrated in FIG. 15.

Die to wafer bonding structures according to the present disclosure may be bonded together to form a 3D-IC.

First, referring to FIG. 17, die to wafer bonding structures according to the present disclosure may be bonded such that each semiconductor die 21 faces each other. For example, the die to wafer bonding structure 1A illustrated in FIG. 1 and the die to wafer bonding structure 1B illustrated in FIG. 3 may be bonded such that the respective semiconductor dies 21 face each other.

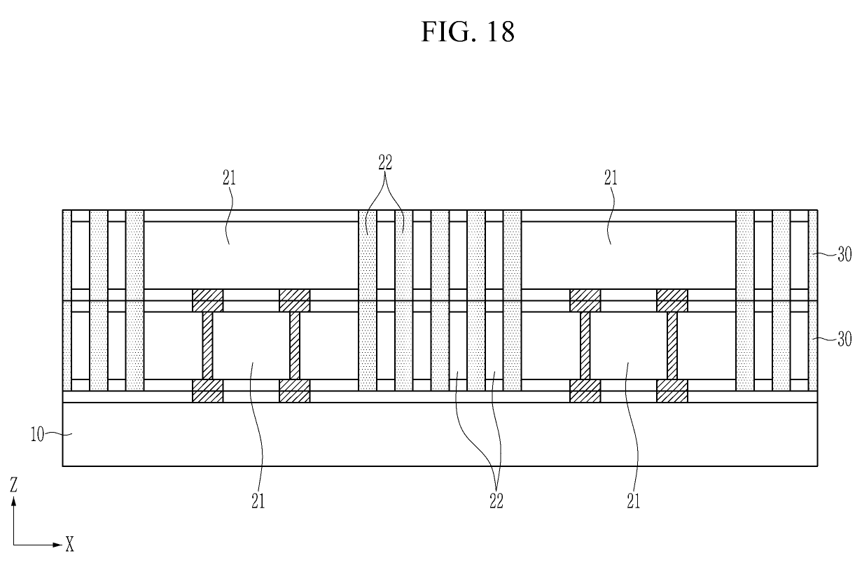

Next, referring to FIG. 18, the wafer structure 10 of the die to wafer bonding structure 1B disposed on the upper side may be removed. The wafer structure 10 may be removed by, for example, grinding.

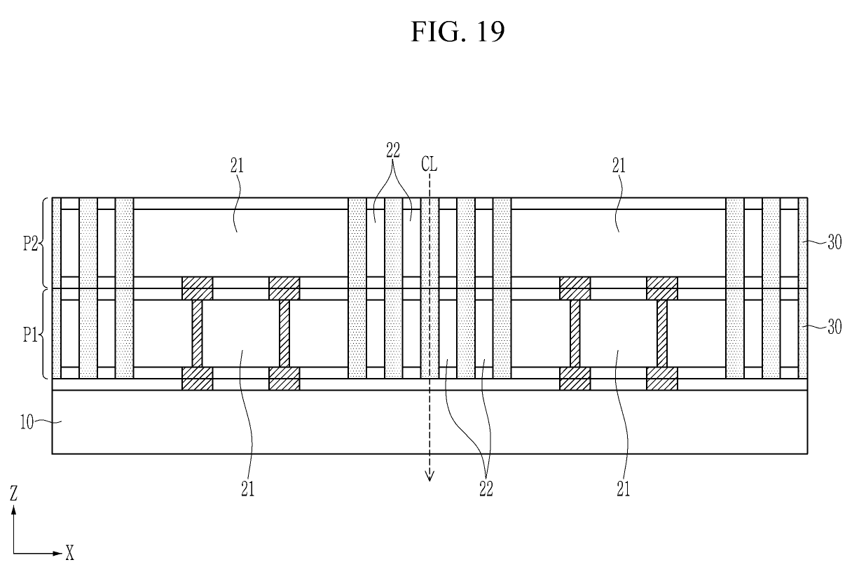

Next, referring to FIG. 19, the die to wafer bonding structures 1A and 1B may be cut along cutting lines CL to manufacture a semiconductor package 2A.

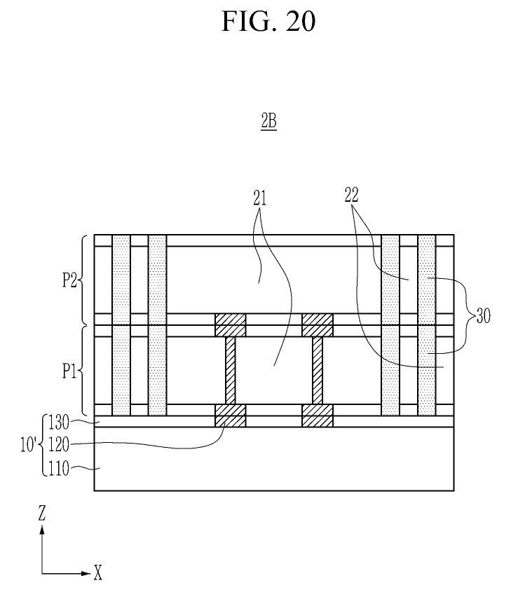

FIG. 20 is a cross-sectional view of a semiconductor package according to another embodiment.

The dummy structures 22 arranged at the outermost side of a semiconductor package 2B may be exposed from the insulation material 30 to consist a side surface of the semiconductor package 2B.

For other configurations, the same explanations as specifically described elsewhere in the present disclosure may be applied.

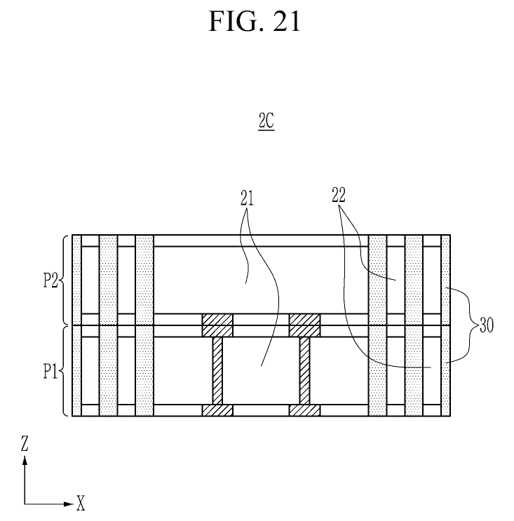

FIG. 21 is a cross-sectional view of a semiconductor package according to another embodiment.

A semiconductor package 2C may not include the substrate 10'. For example, if the wafer structure 10 is used as a carrier substrate, the wafer structure 10 may be removed.

For other configurations, the same explanations as specifically described elsewhere in the present disclosure may be applied.

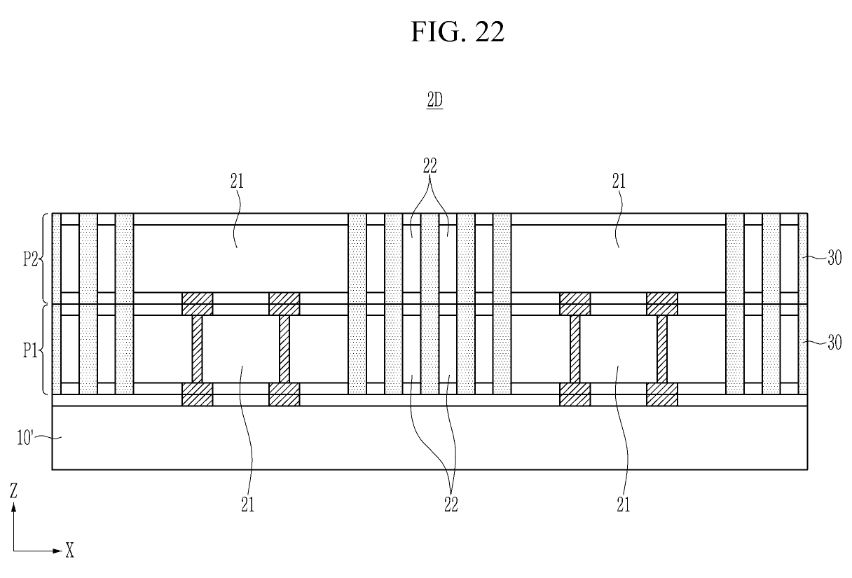

FIG. 22 is a cross-sectional view of a semiconductor package according to another embodiment.

Each of the plurality of sub-packages P1 and P2 of a semiconductor package 2D may include a plurality of semiconductor dies 21 spaced apart from each other. The semiconductor dies 21 of each of the plurality of sub-packages P1 and P2 may overlap in the Z direction, and be electrically connected to each other.

The substrate 10' may be an interposer substrate. The substrate 10' may electrically connect, for example, the plurality of semiconductor dies 21 of the first sub-package P1.

For other configurations, the same explanations as specifically described elsewhere in the present disclosure may be applied.

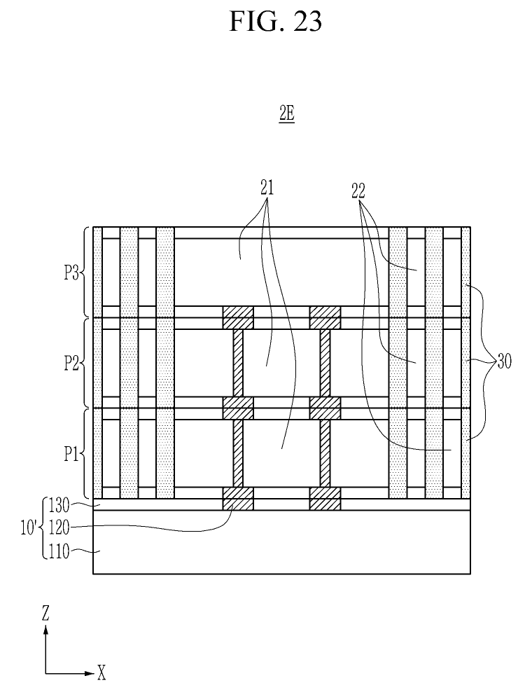

FIG. 23 is a cross-sectional view of a semiconductor package according to another embodiment.

A semiconductor package 2E may further include a third sub-package P3 arranged on the second sub-package P2. By sequentially repeating the process of attaching a die to wafer bonding structure on the die to wafer bonding structure disposed at the bottom side and removing a wafer structure 10 of the attached die to wafer bonding structure, the number of sub-packages to be stacked can be controlled.

For other configurations, the same explanations as specifically described elsewhere in the present disclosure may be applied.

FIG. 24 and FIG. 25 are drawings showing a partial manufacturing process of a die to wafer bonding structure according to a comparative example.

The die to wafer bonding structure according to a comparative example does not include dummy structures 22. In the case of the die to wafer bonding structure according to the comparative example, dishing of the insulation material 30 may occur in the region between the semiconductor dies 21 during the process of removing the upper surface of the insulation material 30 by chemical mechanical polishing. Controlling dishing of the insulation material increases process difficulty and cost, and the dishing that occurs may cause a decrease in product yield due to voids between insulation materials in subsequent processes.

In contrast, according to the present disclosure, dishing of the insulation material may be prevented by introducing dummy structures between semiconductor dies. Therefore, process difficulty and cost increase for dishing control of the insulation material are not required, and voids between insulation materials due to dishing and a decrease in product yield due to voids can be prevented.

Although the embodiment of the present disclosure has been described in detail above, the scope of the present disclosure is not limited thereto, and various modifications and improvements of a person of an ordinary skill in the art utilizing the basic concept of the present disclosure defined in the following claims also fall within the scope of the present disclosure.

Additionally, the embodiments of the present disclosure are not independent of each other and may be implemented in combination with each other unless specifically contradictory. Accordingly, the combined embodiment of the present disclosure should also be considered as included in the present disclosure.

What is claimed is:

1. A die to wafer bonding structure comprising:
a wafer structure;
a semiconductor die disposed on the wafer structure and having a first surface facing the wafer structure and a second surface opposite to the first surface, the semiconductor die including a first conductive pad disposed on the second surface;
a plurality of dummy structures spaced apart from the semiconductor die on the wafer structure; and
an insulation material surrounding each of the semiconductor die and the plurality of dummy structures.

2. The die to wafer bonding structure of claim 1, wherein
the plurality of dummy structures are arranged to surround the semiconductor die.

3. The die to wafer bonding structure of claim 1, wherein:
each of the plurality of dummy structures includes a first surface facing the wafer structure and a second surface opposite to the first surface of each of the plurality of dummy structures, and
the second surface of the semiconductor die and the second surfaces of the plurality of dummy structures are exposed from the insulation material.

4. The die to wafer bonding structure of claim 1, wherein
a thickness of the semiconductor die and a thickness of the plurality of dummy structures are substantially the same.

5. The die to wafer bonding structure of claim 1, wherein
a distance between the semiconductor die and a dummy structure most adjacent to the semiconductor die among the plurality of dummy structures is 50 µm or more and 100 µm or less.

6. The die to wafer bonding structure of claim 1, wherein
a distance between adjacent dummy structure of the plurality of dummy structures is 50 µm or more and 100 µm or less.

7. The die to wafer bonding structure of claim 1, wherein
each of the plurality of dummy structures includes a semiconductor substrate.

8. The die to wafer bonding structure of claim 7, wherein
the semiconductor die further includes a first insulation layer covering a side surface of the first conductive pad, and
each of the plurality of dummy structures includes a second insulation layer disposed on one surface of the semiconductor substrate facing away from the wafer structure.

9. The die to wafer bonding structure of claim 8, wherein
the semiconductor die further includes a second conductive pad disposed on the first surface of the semiconductor die and a through via electrically connecting the first conductive pad and the second conductive pad.

10. The die to wafer bonding structure of claim 9, wherein
the semiconductor die further includes a third insulation layer covering a side surface of the second conductive pad, and
each of the plurality of dummy structures includes a fourth insulation layer disposed on another surface of the semiconductor substrate facing the wafer structure.

11. A die to wafer bonding structure comprising:
a wafer structure;
a first semiconductor die disposed on the wafer structure;
a second semiconductor die spaced apart from the first semiconductor die in a first direction on the wafer structure;
a third semiconductor die spaced apart from the first semiconductor die in a second direction intersecting the first direction on the wafer structure;
a fourth semiconductor die spaced apart from the second semiconductor die in the second direction on the wafer structure;
a plurality of first dummy structures including a plurality of first-first dummy structures disposed between the first semiconductor die and the second semiconductor, a plurality of first-second dummy structures disposed between the first semiconductor die and the third semiconductor, a plurality of first-third dummy structures disposed between the second semiconductor die and the fourth semiconductor, and a plurality of first-fourth dummy structures disposed between the third semiconductor die and the fourth semiconductor;
a plurality of second dummy structures surrounded by the plurality of first-first dummy structures, the plurality of first-second dummy structures, the plurality of first-third dummy structures and the plurality of first-fourth dummy structures; and
an insulation material surrounding each of the first semiconductor die, the second semiconductor die, the third semiconductor die, the fourth semiconductor die, the plurality of first dummy structures, and the plurality of second dummy structures.

12. The die to wafer bonding structure of claim 11, wherein
the plurality of first-first dummy structures and the plurality of first-fourth dummy structures are arranged along the first direction, respectively, and
the plurality of first-second dummy structures and the plurality of first-third dummy structures are arranged along the second direction, respectively.

13. The die to wafer bonding structure of claim 11, wherein
The second dummy structures include a second-first dummy structure, a second-second dummy structure spaced apart from the second-first dummy structure in the first direction, a second-third dummy structure spaced apart from the second-first dummy structure in the second direction, and a second-fourth dummy structure spaced apart from the second-second dummy structure in the second direction.

14. A semiconductor package comprising:
a first sub-package including a first semiconductor die, a plurality of first dummy structures spaced apart from the first semiconductor die, and a first insulation material surrounding each of the first semiconductor die and the plurality of first dummy structures; and
a second sub-package disposed on the first sub-package, comprising a second semiconductor die disposed on the first semiconductor die and electrically connected to the first semiconductor die, a plurality of second dummy structures spaced apart from the second semiconductor die, and a second insulation material surrounding each of the second semiconductor die and the plurality of second dummy structures.

15. The semiconductor package of claim 14, wherein
the plurality of first dummy structures are arranged to surround the first semiconductor die, and
the plurality of second dummy structures are arranged to surround the second semiconductor die.

16. The semiconductor package of claim 14, wherein
the second insulation material is in contact with the first insulation material.

17. The semiconductor package of claim 14, wherein
the second semiconductor die is in contact with the first semiconductor die.

18. The semiconductor package of claim 14, wherein
the plurality of second dummy structures are in contact with the plurality of first dummy structures.

19. The semiconductor package of claim 14, further comprising:
a substrate spaced apart from the second sub-package with the first sub-package interposed therebetween and electrically connected to the first semiconductor die.

20. The semiconductor package of claim 19, wherein
the first sub-package further includes a third semiconductor die spaced apart from the first semiconductor die,
the second sub-package further includes a fourth semiconductor die spaced apart from the second semiconductor die and is disposed on the third semiconductor die and electrically connected to the third semiconductor die,
and the substrate electrically connects the first semiconductor die and the third semiconductor die.
